(19) United States
(12) Patent Application Publication
(10) Pub. No.: US 2008/0303939 A1
(43) Pub. Date: Dec. 11, 2008

(54) CAMERA MODULE WITH COMPACT PACKAGING OF IMAGE SENSOR CHIP

(75) Inventors: PO-CHIH HSU, Tu-Cheng (TW); MING-YUAN LIN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/925,293

(22) Filed: Oct. 26, 2007

(30) Foreign Application Priority Data
Jun. 7, 2007 (CN) 200710200784.2

(51) Int. Cl. H04N 5/225; H01L 27/00

(52) U.S. Cl. 348/374; 348/340; 250/208.1

(57) ABSTRACT

An exemplary camera module includes a base, an image sensor chip, a lens holder, a lens module, at least one electronic element, and a light transmittance element. The base defines a first cavity. The image sensor chip is disposed on the base and includes a photosensitive area. The image sensor chip covers the first cavity. The lens holder is disposed on the base. The lens holder includes a first chamber and a second chamber disposed on the base. The second chamber covers the image sensor chip. The lens module is partially received in the first chamber. The lens module is optically aligned with the image sensor chip. The at least one electronic element is disposed in the first cavity. The light transmittance element is fixed on the image sensor chip. The light transmittance element is received in the second chamber and contacts the second chamber.

### TECHNICAL FIELD

The present invention relates to camera modules and, particularly, to a camera module having a compact packaging of image sensor chip.

### BACKGROUND

With the ongoing development of micro-circuitry and multimedia technology, digital cameras have now entered widespread use. High-end portable electronic devices, such as mobile phones and PDAs (Personal Digital Assistants), are being developed to be increasingly multi-functional. Many of these portable electronic devices are equipped with digital cameras. A key component of the digital cameras is a camera module. To facilitate portability, the camera module tends to be compact, slim, and light.

FIG. 4 illustrates a typical camera module 400. The camera module 400 includes a lens module 402, a lens holder 403, an image sensor chip 404, a base 405, and a transparent cover 406. The lens module 402 is partially received in and threadingly engaged with the lens holder 403. The image sensor chip 404 is typically attached to the base 405. The transparent cover 406 is adhered to the image sensor chip 404. A plurality of electronic elements 407 is disposed on the base around the image sensor chip 404. The transparent cover 406, the electronic element 407, and the image sensor chip 404 are received in the lens holder 403.

In the camera module 400, the base 405 needs to provide sufficient space not only for the image sensor chip 404 and the electronic elements 407 but also to allow the mounting of the lens holder 403. Thus, this kind of camera module 400 has a relative larger size and volume. To reduce the size and volume of the camera module 400 to a certain degree, an approach has been developed, whereby an end portion 413 of the lens holder 403 is made thinner. However, such a thin lens holder 403 is not easily manufactured by an injection molding method. This difficulty results in a relative high cost. As such, the camera module 400 has not proven to be economically suitable for slim and compact electronic products.

What is needed, therefore, is a camera module that is a relative compact and slim and that is economical to produce.

### SUMMARY

In accordance with an embodiment, a camera module includes a base, an image sensor chip, a lens holder, a lens module, at least one electronic element, and a light transmittance element. The base defines a first cavity. The image sensor chip is disposed on the base and includes a photosensitive area. The image sensor chip covers the first cavity. The lens holder is disposed on the base. The lens holder includes a first chamber and a second chamber disposed on the base. The second chamber covers the image sensor chip. The lens module is partially received in the first chamber of the lens holder. The lens module is optically aligned with the image sensor chip. The at least one electronic element is disposed in the first cavity and is structurally and electrically connected to the base. The light transmittance element is fixed on the image sensor chip. The light transmittance element is receiving in the second chamber and contacts an internal circumferential surface of the second chamber.

Other advantages and novel features will be drawn from the following detailed description of at least one present embodiment, when considered in conjunction with the attached drawings.

### BRIEF DESCRIPTION OF THE DRAWINGS

Many aspects of the present camera module can be better understood with reference to the following drawings. The components in the drawings are not necessarily drawn to scale, the emphasis instead being placed upon clearly illustrating the principles of the present camera module. Moreover, in the drawings, like reference numerals designate corresponding parts throughout the several views.

FIG. 1 is a schematic, cross-sectional view of a camera module, according to a first present embodiment.

FIG. 2 is a schematic, cross-sectional view of an alternative camera module, according to a second present embodiment.

FIG. 3 is a schematic, cross-sectional view of another alternative camera module, according to a third present embodiment.

FIG. 4 is a schematic, cross-sectional view of a conventional camera module.

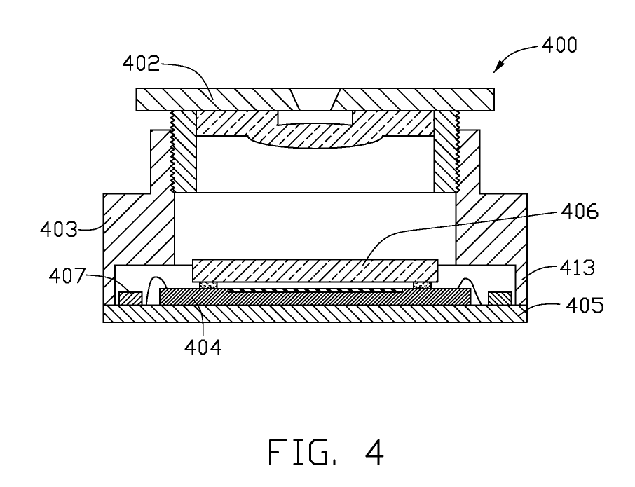

### DETAILED DESCRIPTION OF PREFERRED EMBODIMENTS

Embodiments of the present camera module thereof will now be described in detail below and with reference to the drawings.

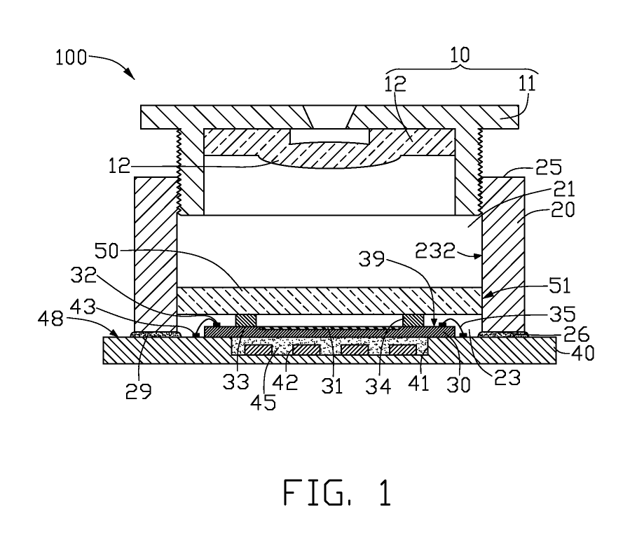

FIG. 1 illustrates a camera module 100, in accordance with a first present embodiment. The camera module 100 includes a lens module 10, a lens holder 20, an image sensor chip 30, a base 40, a light transmittance element 50, and at least one electronic element 42.

The image sensor chip 30 is disposed on the base 40. The lens module 10 is, advantageously, threadingly engaged with the lens holder 20. The lens holder 20 is disposed on the base 40 and receives the image sensor chip 30 and the light transmittance element 50 therein. The light transmittance element 50 is adhered to the image sensor chip 30.

The lens module 10 usefully includes a lens barrel 11 and a lens assembly 12. The lens module 10 is optically aligned with the image sensor chip 30 and the light transmittance element 50. The lens barrel 11 is, advantageously, a hollow cylinder configured for receiving the lens assembly 12 therein. The lens barrel 11 is, usefully, threadingly engaged with the lens holder 20. In the illustrated embodiment, the lens assembly 12 includes one lens. In other embodiments, the lens assembly 12 could include two or more lenses received in the lens barrel 11.

The lens holder 20 has a front end 25 and a rear end 26 facing away from the front end 25. The lens holder 20 defines a first chamber 21 adjacent to the front end 25 and a second chamber 23 adjacent to the rear end 26. The first chamber 21 and the second chamber 23 are configured for receiving the lens module 10 and the light transmittance element 50 therein, respectively. The rear end 26 of the lens holder 20 is disposed on the base 40.

The base 40 is, advantageously, a printed circuit board. The base 40 has a top surface 48 with the image sensor chip 30 installed thereon. The base 40 defines a first cavity 41. The at least one electronic element 42 is received in the first cavity 41. The at least one electronic element 42 is selected from the group consisting of: a passive element, a driving chip, a signal-processing chip, and combinations thereof. The image sensor chip 30 covers and spans the first cavity 41. A plurality of base pads 43 is disposed on the top surface 48 of the base 40 and surrounds the image sensor chip 30. The base 40 is, beneficially, made of a material selected from the group consisting of: polyester, polyimide, ceramic, and glass fiber.

The first cavity 41 is a rectangular cavity. The first cavity 41 is, advantageously, filled with adhesive material 45, for covering the at least one electronic element 42. Thus, the at least one electronic element 42 is tightly fixed in the first cavity 41. The at least one electronic element 42 is electrically connected to the base 40. The image sensor chip 30 beneficially covers the first cavity 41 and is adhered to the adhesive material 45.

The image sensor chip 30 is, advantageously, a charged coupled device (CCD), or a complementary metal-oxide-semiconductor transistor (CMOS). The image sensor chip 30 is able to convert the received light signals into digital electrical signals.

The image sensor chip 30 is adhered onto the base 40, e.g., via an adhesive layer 29. The image sensor chip 30 is, beneficially, optically aligned with the lens module 10 (e.g., the lens assembly 12). For example, an optical axis of the lens assembly 12 is aligned with that the image sensor chip 30.

The image sensor chip 30 has an upper surface 39 facing the lens module 10. The image sensor chip 30 includes a photosensitive (i.e., active) area 31 disposed on the upper surface 39 and a non-photosensitive area 33 surrounding the photosensitive area 31. The photosensitive area 31 is configured (i.e., structured and arranged) for receiving light signals transmitted through the lens module 10 and the light transmittance element 50.

A plurality of chip pads 32 is disposed on the non-photosensitive area 33 of the image sensor chip 30 and surrounds the photosensitive area 31. Each chip pad 251 is electrically connected to a corresponding base pad 43, e.g., via a respective wire 35. The wires 35 are, advantageously, made of a conductive material, such as gold, silver, aluminum, or an alloy thereof.

The light transmittance element 50 is fixed on the image sensor chip 30, e.g., via a bonding layer 34. The light transmittance element 50 together with the bonding layer 34 hermetically seals the photosensitive area 31. A lateral surface 51 of the light transmittance element 50 is in contact with an inner circumferential surface 232 of the lens holder 20 surrounding the second chamber 23. The light transmittance element 50, the base 40, and the lens holder 20 cooperatively form a protective package for the image sensor chip 30.

On one hand, the base 40 defines the first cavity 41 for receiving the at least one electronic element 42 therein. Thus, the at least one electronic element 42 does not occupy special space at the top face 48 of the base 40. Accordingly, dimension of the base 40 is reduced, thereby achieving compact structure of the camera module 100.

On the other hand, the light transmittance element 50 is in contact with the lens holder 20, thereby facilitating alignment between the lens holder 20 and the image sensor chip 30. Thus, the lens module 10 is readily aligned with the image sensor chip 30. Accordingly, the camera module 100 can obtain a high image quality.

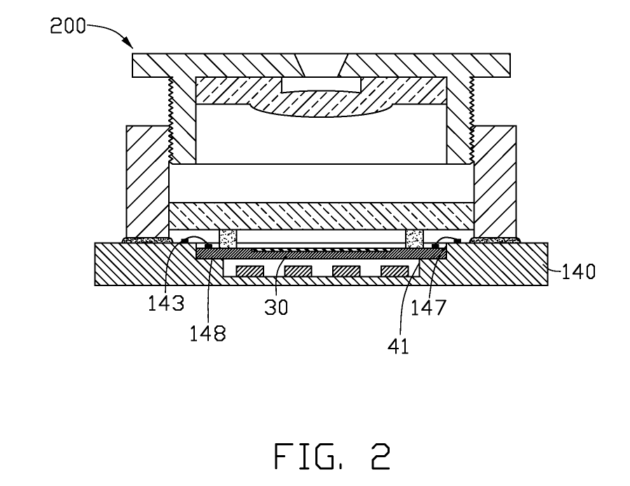

FIG. 2 illustrates a camera module 200 in accordance with a second present embodiment. The camera module 200 is essentially similar to the camera module 100, except for the base 140 thereof.

In this embodiment, the base 140 defines a second cavity 147 at the edges around the first cavity 41. The second cavity 147 is a rectangular cavity. The second cavity 147 is in communication with the first cavity 41. The second cavity 147 is, advantageously, axially aligned with the first cavity 41. The two cavities 41, 147 cooperatively form a step-shaped cavity. Thus, a step 148 is formed at a bottom of the second cavity 147 and surrounds the first cavity 41. The step 148 supports the image sensor chip 30 thereon. A plurality of base pads 143 is disposed around the edges of the second cavity 147 and each is similar to the base pads 43 in the camera module 100 shown in FIG. 1.

Because the image sensor chip 30 is received in the second cavity 147, total height of the camera module 200 is lowered. Accordingly, the dimensions of the camera module 200 are effectively reduced.

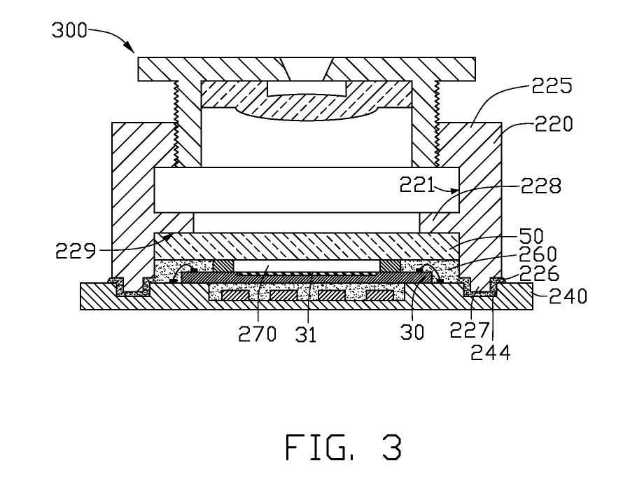

FIG. 3 illustrates a camera module 300, in accordance with a third present embodiment. The camera module 300 is essentially similar to the camera module 100 in the first embodiment, except for the lens holder 220 and the base 240.

In this embodiment, the lens holder 220 includes a front end 225, a rear end 226, a plurality of pins 227, and a circular shoulder 228. The front end 225 and the rear end 226 are essentially similar to the front end 25 and the rear end 26 in the first embodiment, respectively. The plurality of pins 227 protrudes out of the rear end 226 of the lens holder 220. The base 240 defines a plurality of grooves 244. Each groove 244 corresponds to one respective pin 227, for receiving the respective pin 227 therein. Alternatively, the grooves 244 could run through the base 244.

The base 240, the lens holder 220, and the light transmittance element 50 cooperatively define an interspace 270. The image sensor chip 30 is packaged in the interspace 270. A bonding layer 260 is, advantageously, disposed in the interspace 270 and surrounds the photosensitive area 31 of the image sensor chip 30. A part of the bonding layer 260 beneficially fills the grooves 244, thereby fixing the pins 226 in the grooves 244.

The shoulder 228 protrudes out of an inner circumferential face 221 of the lens holder 220. The shoulder 228 has a bottom-most surface 229 facing the image sensor chip 30. The light transmittance element 50 is advantageously adhered to the bottom-most surface 229 of the shoulder 228; thereby facilitating alignment of the lens holder 220 and the light transmittance element 50.

In the camera module 300, the lens holder 220 is disposed on the base 240 by aligning the pins 227 with the grooves 244, thus further facilitating accurately alignment of the lens holder 220 and the base 240.

It will be understood that the above particular embodiments and methods are shown and described by way of illustration only. The principles and features of the present invention may be employed in various and numerous embodiments thereof without departing from the scope of the invention as claimed. The above-described embodiments illustrate the scope of the invention but do not restrict the scope of the invention.

What is claimed is:

1. A camera module comprising:
a base defining a first cavity;
an image sensor chip disposed on the base, the image sensor chip comprising a photosensitive area, the image sensor chip covering the first cavity;
a lens holder disposed on the base, the lens holder comprising a first chamber and a second chamber disposed on the base, the second chamber covering the image sensor chip;
a lens module partially received in the first chamber of the lens holder, the lens module being optically aligned with the image sensor chip;
at least one electronic element disposed in the first cavity, the at least one electronic element being structurally and electrically connected to the base; and
a light transmittance element fixed on the image sensor chip, the light transmittance element being received in the second chamber and contacting an internal circumferential surface of the second chamber.

2. The camera module as claimed in claim 1, wherein the base defines a second cavity at edges around the first cavity, the second cavity communicating with the first cavity, a step being formed at a bottom of the second cavity and surrounding the first cavity, the step supporting the image sensor chip thereon.

3. The camera module as claimed in claim 2, wherein the second cavity is axially aligned with the first cavity.

4. The camera module as claimed in claim 2, wherein a plurality of chip pads is disposed at the image sensor chip around the photosensitive area, a plurality of base pads being disposed at edges of the base around the second cavity, each chip pad being electrically connected to one respective base pad.

5. The camera module as claimed in claim 1, wherein a plurality of pins protrudes out of a bottom-most face of the lens holder, the base defining a plurality of grooves, each groove being configured for receiving one respective pin therein.

6. The camera module as claimed in claim 5, wherein the grooves further run through the base.

7. The camera module as claimed in claim 1, wherein a plurality of chip pads is disposed at the image sensor chip around the photosensitive area, a plurality of base pads being disposed at edges of the base around the first cavity, each chip pad being electrically connected to one respective base pad.

8. The camera module as claimed in claim 1, wherein the at least one electronic element is selected from the group consisting of: a passive element, a driving chip, a signal-processing chip, and combinations thereof.

9. The camera module as claimed in claim 1, wherein a circular shoulder protrudes inward from the inner circumferential face of the second chamber, the light transmittance element being fixed to a bottom-most surface of the circular shoulder.

10. The camera module as claimed in claim 1, wherein the base, the lens holder, and the light transmittance element cooperatively defines an interspace in which the image sensor chip and the at least one electronic element is received, a bonding layer being disposed on the image sensor chip and surrounding the photosensitive area of the image sensor chip.

11. The camera module as claimed in claim 10, wherein the bonding layer is adhered with the base, the lens holder, and the light transmittance element.

12. The camera module as claimed in claim 1, wherein adhesive is received in the first cavity and covers the at least one electronic element.

13. The camera module as claimed in claim 12, wherein the adhesive is made of an adhesive material selected from the group consisting of: silicone, epoxy, acrylic, and polyamide adhesive.

14. A camera module comprising:
a base defining a first cavity and a second cavity communicating with the first cavity with a step formed therebetween;
an image sensor chip comprising a photosensitive area, the image sensor chip disposed on the step of the base and received in the second cavity to cover the first cavity;
a lens holder disposed on the base, the lens holder covering the image sensor chip;
a lens module partially received in the lens holder, the lens module being optically aligned with the image sensor chip; and
at least one electronic element disposed in the first cavity, the at least one electronic element being structurally and electrically connected to the base.

15. The camera module as claimed in claim 14, wherein a light transmittance element is adhered onto the image sensor chip, the light transmittance element being received in the lens holder and contacting an internal circumferential surface of the lens holder.

16. The camera module as claimed in claim 14, wherein a plurality of chip pads is disposed on the image sensor chip around the photosensitive area, a plurality of base pads being disposed at edges of the base around the second cavity, each chip pad being electrically connected to one respective base pad.

17. The camera module as claimed in claim 14, wherein a plurality of pins protrudes out of a bottom-most face of the lens holder, the base defining a plurality of grooves, each groove being configured for receiving one respective pin therein.

18. The camera module as claimed in claim 14, wherein the grooves further run through the base.

19. A camera module comprising:
a base comprising a top surface and a first cavity sunken from the top surface;
an image sensor chip disposed on the base and covering the first cavity; a plurality of electronic elements disposed in the first cavity and covered by the image sensor chip, the at least one electronic element being electrically connected to the base;
a lens holder disposed on the top surface of the base, the lens holder covering the image sensor chip;
a lens module partially received in the lens holder, the lens module being optically aligned with the image sensor chip;
a light transmittance element being received in the lens holder and fixed on the image sensor chip.

20. The camera module as claimed in claim 19, wherein a periphery of the light transmittance element contacts with an internal circumferential surface of the lens holder.
